(19) United States
(12) Patent Application Publication
(10) Pub. No.: US 2026/0181081 A1
(43) Pub. Date: Jun. 25, 2026

(54) ELECTRONIC DEVICE

(71) Applicant: SEIKO EPSON CORPORATION, Tokyo (JP)

(72) Inventors: Kyo HORIE, Okaya (JP); Koichi KASHU, Shiojiri (JP); Toru MATSUYAMA, Matsumoto (JP)

(21) Appl. No.: 19/430,390

(22) Filed: Dec. 23, 2025

(30) Foreign Application Priority Data
Dec. 25, 2024 (JP) 2024-228618

(51) Int. Cl. H04N 1/00; H05K 1/14

(52) U.S. Cl. CPC H04N 1/00315; H04N 1/00557; H04N 1/00559; H05K 1/144; H04N 2201/0082; H05K 2201/042; H05K 2201/10098

(57) ABSTRACT

Provided is an electronic device including: a first substrate; a second substrate; and a coupling component that couples the first substrate and the second substrate, and transmits an electric signal between the first substrate and the second substrate, in which the second substrate is supported by a clay-like support column having an electrical insulation property with respect to the first substrate.

The present application is based on, and claims priority from JP Application Serial Number 2024-228618, filed Dec. 25, 2024, the disclosure of which is hereby incorporated by reference herein in its entirety.

### BACKGROUND

### 1. Technical Field

The present disclosure relates to an electronic device.

### 2. Related Art

In recent years, an electronic device including a plurality of circuit substrates has become widespread. In such an electronic device, for example, there may be a case where it is necessary to detach one circuit substrate from the electronic device among the plurality of circuit substrates. Therefore, in the related art, various electronic devices in which one circuit substrate among the plurality of circuit substrates can be detached from the electronic device are proposed. For example, JP-A-2022-157499 discloses an electronic device in which one circuit substrate can be detached from the electronic device by coupling one circuit substrate to a substrate on a main body side of the electronic device with a detachable coupling component such as a connector.

However, when two circuit substrates are coupled to each other by a coupling component such as a connector, a change in a relative position or posture between the two circuit substrates may occur due to a vibration or the like of the electronic device. When the change in the relative position or posture between the two circuit substrates occurs, a surface damage may occur between the circuit substrate and the coupling component. In addition, due to the surface damage between the circuit substrate and the coupling component, a fragment may be separated from one or both of the circuit substrate and the coupling component, and a problem may occur in the electronic device due to the separated fragment.

### SUMMARY

To solve the above problems, according to an aspect of the present disclosure, there is provided an electronic device including: a first substrate; a second substrate; and a coupling component that couples the first substrate and the second substrate, and transmits an electric signal between the first substrate and the second substrate, in which the second substrate is supported by a clay-like support column having an electrical insulation property with respect to the first substrate.

### BRIEF DESCRIPTION OF THE DRAWINGS

FIG. 1 is a perspective view illustrating an example of a schematic external configuration of an ink jet printer according to a first embodiment of the present disclosure.

FIG. 2 is a perspective view illustrating an example of the schematic external configuration of the ink jet printer.

FIG. 3 is a block diagram illustrating an example of the configuration of the ink jet printer.

FIG. 4 is a perspective view illustrating an example of a schematic internal structure of the ink jet printer.

FIG. 5 is a cross-sectional view illustrating an example of a structure of an ejection portion.

FIG. 6 is a block diagram illustrating an example of a configuration of a head unit.

FIG. 7 is a timing chart illustrating an example of a signal supplied to the head unit.

FIG. 8 is an explanatory view illustrating an example of an individual designation signal.

FIG. 9 is a block diagram illustrating an example of a configuration of a drive signal generation circuit.

FIG. 10 is an exploded perspective view illustrating an example of a structure of a drive control unit and a wireless communication unit.

FIG. 11 is a cross-sectional view illustrating an example of a structure of the drive control unit and the wireless communication unit.

FIG. 12 is a schematic view illustrating an example of a support column.

FIG. 13 is a cross-sectional view illustrating an example of a structure of an ink jet printer according to a comparative example.

FIG. 14 is a perspective view illustrating an example of a schematic external configuration of a smartphone according to a second embodiment of the present disclosure.

FIG. 15 is a block diagram illustrating an example of a configuration of the smartphone.

FIG. 16 is a cross-sectional view illustrating an example of a structure of the smartphone.

FIG. 17 is a cross-sectional view illustrating an example of a structure of an ink jet printer according to Modification Example 1 of the present disclosure.

### DESCRIPTION OF EMBODIMENTS

Hereinafter, embodiments for carrying out the present disclosure will be described with reference to the drawings. Meanwhile, a dimension and a scale of each portion are different from actual ones as appropriate in each drawing. The embodiments described below are preferred specific examples of the present disclosure and are thus added with technically preferred various limitations, but the scope of the present disclosure is not limited to such embodiments unless description for limiting the present disclosure is made in the following description.

### A. First Embodiment

In a first embodiment, a printing device will be described by exemplifying an ink jet printer 1 that ejects ink to form an image on recording paper PP.

### A. 1. Overview of Ink Jet Printer 1

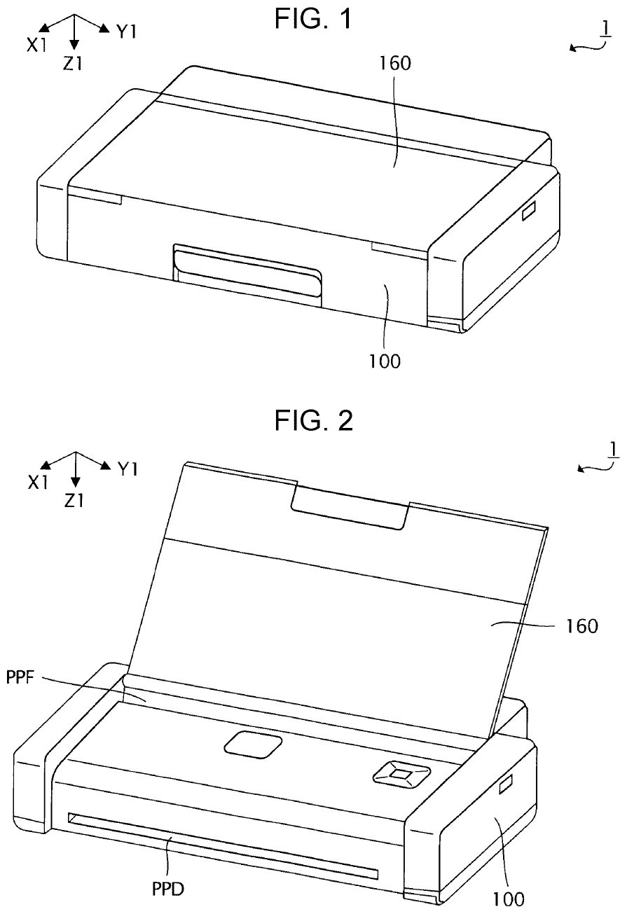

Hereinafter, an example of a configuration of an ink jet printer 1 according to the first embodiment will be described with reference to FIGS. 1 to 5.

FIGS. 1 and 2 are external perspective views illustrating an example of an external appearance of the ink jet printer 1.

As illustrated in FIGS. 1 and 2, the ink jet printer 1 is a mobile printer that can be carried by a user of the ink jet printer 1, and includes a housing 100, an openable/closable cover member 160, a paper feed port PPF for feeding the recording paper PP to the inside of the ink jet printer 1, and a paper discharge port PPD for discharging the recording paper PP from the ink jet printer 1.

Note that in the following, a front surface direction of the ink jet printer 1 is referred to as an X1 direction, a rear surface direction of the ink jet printer 1 is referred to as an X2 direction, and the X1 direction and the X2 direction are collectively referred to as an X-axis direction. In addition, when the ink jet printer 1 is viewed in the X2 direction, a right direction of the ink jet printer 1 is referred to as a Y1 direction, a left direction of the ink jet printer 1 is referred to as a Y2 direction, and the Y1 direction and the Y2 direction are collectively referred to as a Y-axis direction. In addition, a down direction of the ink jet printer 1 is referred to as a Z1 direction, an up direction is referred to as a Z2 direction, and the Z1 direction and the Z2 direction are collectively referred to as a Z-axis direction. In the present embodiment, as an example, a description will be made on the assumption that the X-axis direction, the Y-axis direction, and the Z-axis direction are orthogonal to each other. Meanwhile, the present disclosure is not limited to such an aspect. The X-axis direction, the Y-axis direction, and the Z-axis direction may intersect each other.

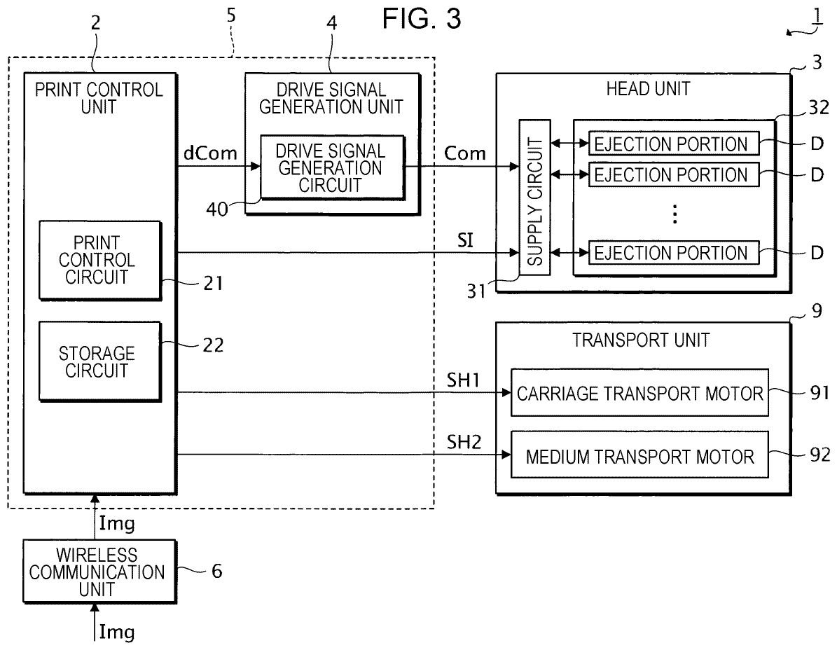

FIG. 3 is a functional block diagram illustrating an example of the configuration of the ink jet printer 1.

As illustrated in FIG. 3, the ink jet printer 1 is supplied with image data Img indicating an image to be formed by the ink jet printer 1 from a host computer such as a personal computer or a digital camera. The ink jet printer 1 executes a print process of forming an image, which is indicated by the image data Img supplied from the host computer, on the recording paper PP.

As illustrated in FIG. 3, the ink jet printer 1 includes a print control unit 2 that controls each portion of the ink jet printer 1, a head unit 3 provided with an ejection portion D that ejects ink to the recording paper PP, a drive signal generation unit 4 provided with a drive signal generation circuit 40 that generates a drive signal Com for driving the ejection portion D, a wireless communication unit 6 that acquires image data Img by wireless communication, and a transport unit 9 for transporting the head unit 3 and the recording paper PP.

Note that in the present embodiment, the ink jet printer 1 is an example of a “printing device” and an “electronic device”, the head unit 3 is an example of a “print head” and a “drive device”, the image data Img is an example of “image information” and “instruction information”, the recording paper PP is an example of a “medium”, and the transport unit 9 is an example of a “transport mechanism”. In addition, in the following description, the configuration including the print control unit 2 and the drive signal generation unit 4 is referred to as a “drive control unit 5”.

In the present embodiment, it is assumed that the ink jet printer 1 includes one or a plurality of the head units 3. Specifically, in the present embodiment, as an example, it is assumed that the ink jet printer 1 includes four head units 3. Note that in the following description, for convenience of description, as illustrated in FIG. 3, there may be a case where the description is made with focus given to one head unit 3 among the four head units 3.

In the present embodiment, as an example, it is assumed that the drive signal generation unit 4 includes one drive signal generation circuit 40 corresponding to one head unit 3. That is, in the present embodiment, it is assumed that the drive signal generation unit 4 is provided with four drive signal generation circuits 40 corresponding to four head units 3. Meanwhile, the present disclosure is not limited to such an aspect. The drive signal generation unit 4 may include two or more drive signal generation circuits 40 corresponding to one head unit 3. Note that in the following description, for convenience of description, as illustrated in FIG. 3, description may be made with a focus given to one drive signal generation circuit 40 among the four drive signal generation circuits 40.

The print control unit 2 includes a print control circuit 21 and a storage circuit 22.

The storage circuit 22 includes a volatile memory such as a random access memory (RAN) and a non-volatile memory such as a read only memory (ROM), an electrically erasable programmable read-only memory (EEPROM), or a programmable ROM (PROM), and stores various pieces of information such as a control program of the ink jet printer 1.

In addition, the print control circuit 21 includes one or a plurality of central processing units (CPU). However, the print control circuit 21 may be provided with a programmable logic device such as a field-programmable gate array (FPGA) instead of the CPU or in addition to the CPU. The print control circuit 21 executes the control program of the ink jet printer 1 stored in the storage circuit 22 and operates in accordance with the control program to control each part of the ink jet printer 1. Specifically, the print control circuit 21 generates signals for controlling an operation of each part of the ink jet printer 1 such as a designation signal SI, a waveform designation signal dCom, a carriage transport control signal SH1, and a medium transport control signal SH2.

Here, the waveform designation signal dCom is a digital signal for defining a waveform of a drive signal Com. The drive signal Com is an analog signal for driving the ejection portion D. The designation signal SI (an example of the “control signal”) is a digital signal that designates a type of an operation of the ejection portion D. Specifically, the designation signal SI designates whether or not the drive signal Com is supplied to the ejection portion D to designate the type of the operation of the ejection portion D such as presence or absence of ink ejection from the ejection portion D. The carriage transport control signal SH1 and the medium transport control signal SH2 are signals for controlling the transport unit 9.

When a print process is executed, the print control unit 2 generates a signal for controlling the head unit 3 such as the designation signal SI based on image data Img. In addition, when the print process is executed, the print control unit 2 generates a signal for controlling the drive signal generation unit 4 such as the waveform designation signal dCom. Further, when the print process is executed, the print control unit 2 generates a signal for controlling the transport unit 9 such as the carriage transport control signal SH1 and the medium transport control signal SH2. As a result, in the print process, the print control unit 2 controls the transport unit 9 to move the head unit 3 and the recording paper PP, adjusts presence or absence of ink ejection from the ejection portion D, an ink ejection timing, and the like, and controls each part of the ink jet printer 1 such that an image corresponding to the image data Img is formed on the recording paper PP.

As illustrated in FIG. 1, the head unit 3 includes a supply circuit 31 and a head portion 32.

The head portion 32 is provided with M ejection portions D. Here, a value M is a natural number that satisfies “M≥1”. Note that in the following description, among the M ejection portions D provided in the head portion 32, an m-th ejection portion D may be referred to as an ejection portion D[m]. In this case, the variable m is a natural number that satisfies “1≤m≤M”. In addition, in the following description, when a component, a signal, or the like of the ink jet printer 1 corresponds to the ejection portion D[m] among the M ejection portions D, a subscript [m] may be added to a code for representing the component, signal, or the like.

The supply circuit 31 switches whether or not to supply the drive signal Com to the ejection portion D[m] based on the designation signal SI. In the following description, among a plurality of the drive signals Com, a drive signal Com supplied to the ejection portion D[m] may be referred to as a supply drive signal Vin[m].

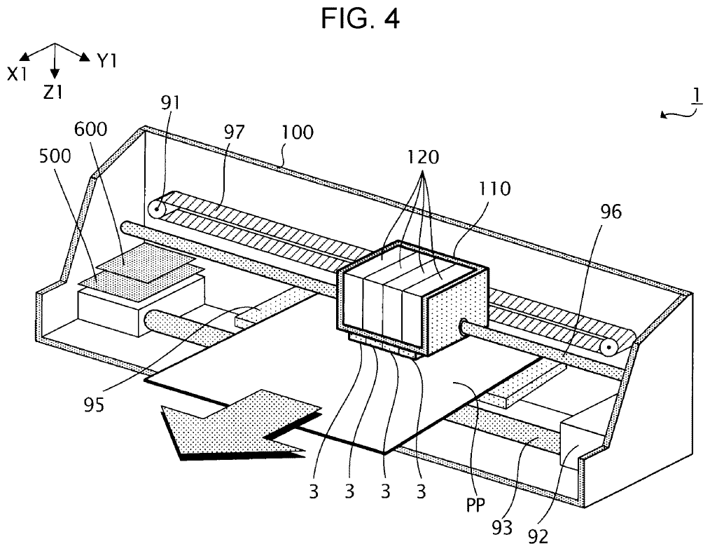

FIG. 4 is a perspective view illustrating an example of a schematic internal structure of the ink jet printer 1.

As illustrated in FIG. 4, in the present embodiment, it is assumed that the ink jet printer 1 is a serial printer. Specifically, when the print process is executed, the ink jet printer 1 ejects ink from the head unit 3 while transporting the recording paper PP in the X1 direction and moving the head unit 3 in the Y1 direction or the Y2 direction to form an image corresponding to the image data Img on the recording paper PP.

As illustrated in FIG. 4, the ink jet printer 1 according to the present embodiment is provided with a housing 100 and a carriage 110 that can reciprocate in the housing 100 in the Y-axis direction.

As illustrated in FIG. 4, in the present embodiment, it is assumed that the carriage 110 is mounted with the four ink cartridges 120 corresponding to four color inks of cyan, magenta, yellow, and black in a one-to-one basis. In addition, in the present embodiment, as described above, it is assumed that the carriage 110 is mounted with four head units 3 corresponding to the four ink cartridges 120 in a one-to-one basis. Each ejection portion D[m] receives ink supplied from each of the ink cartridges 120 corresponding to the head unit 3 provided with the ejection portion D[m]. As a result, each ejection portion D[m] can fill the inside with the supplied ink and eject the ink filled inside the ejection portion D[m] from a nozzle N provided in the ejection portion D[m]. Note that the ink cartridge 120 may be provided outside the carriage 110.

In addition, as described above, the ink jet printer 1 according to the present embodiment is provided with the transport unit 9. As illustrated in FIG. 4, the transport unit 9 includes a carriage transport motor 91, a medium transport motor 92, a medium transport mechanism 93, a platen 95, a carriage guide shaft 96, and a belt 97. The carriage transport motor 91 drives the belt 97 based on the carriage transport control signal SH1. The belt 97 (an example of a “head transport mechanism”) transports the carriage 110 in the Y-axis direction based on the drive of the carriage transport motor 91. The carriage guide shaft 96 supports the carriage 110 to be reciprocable in the Y-axis direction. The medium transport motor 92 drives the medium transport mechanism 93 based on the medium transport control signal SH2. The medium transport mechanism 93 transports the recording paper PP in the X1 direction by rotation based on the drive of the medium transport motor 92. The platen 95 is provided in the Z1 direction of the carriage 110 and supports the recording paper PP transported by the medium transport mechanism 93. As described above, when the print process is executed, the transport unit 9 reciprocates the head unit 3 and the carriage 110 in the Y-axis direction along the carriage guide shaft 96 by the carriage transport motor 91, and transports the recording paper PP on the platen 95 in the X1 direction by the medium transport motor 92 to change a relative position of the recording paper PP with respect to the head unit 3, and the ink can land on the entire recording paper PP. That is, in the present embodiment, the head unit 3 is an example of the “displacement portion”.

As illustrated in FIG. 4, in the present embodiment, it is assumed that the drive control unit 5 includes a control substrate 500 and the wireless communication unit 6 includes a communication substrate 600.

The control substrate 500 (an example of the “first substrate”) is a circuit substrate fixed to the housing 100. The print control circuit 21 and the storage circuit 22 included in the print control unit 2, and the drive signal generation circuit 40 included in the drive signal generation unit 4 are provided on the control substrate 500. In the following description, the circuits provided on the control substrate 500, that is, the print control circuit 21, the storage circuit 22, and the drive signal generation circuit 40 may be referred to as a drive control circuit 50 (an example of the “control circuit”).

The communication substrate 600 (an example of a “second substrate”) is a circuit substrate coupled to the control substrate 500. An antenna 61 and a communication control circuit 62 included in the wireless communication unit 6 are provided on the communication substrate 600. Note that the antenna 61 and the communication control circuit 62 will be described later.

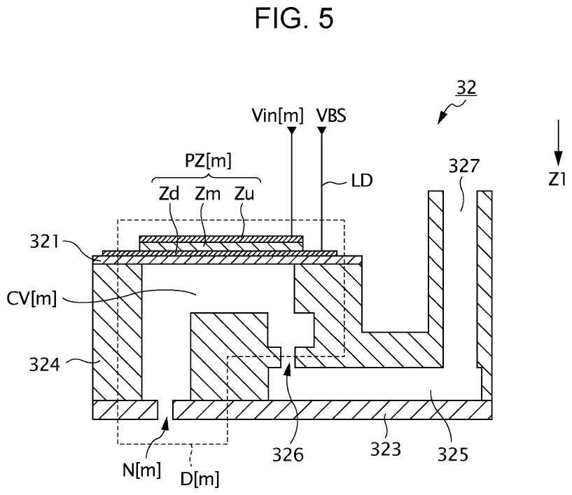

FIG. 5 is a schematic partial cross-sectional view of the head portion 32 in which the head portion 32 is cut to include the ejection portion D[m].

As illustrated in FIG. 5, the ejection portion D[m] is provided with a piezoelectric element PZ[m], a cavity CV[m] filled with the ink, a nozzle N[m] that communicates with the cavity CV[m], and a vibration plate 321. The ejection portion D[m] ejects the ink in the cavity CV[m] from the nozzle N[m] by driving the piezoelectric element PZ[m] by the supply drive signal Vin[m]. The cavity CV[m] is a space partitioned by a cavity plate 324, a nozzle plate 323 in which the nozzle N[m] is formed, and the vibration plate 321. The cavity CV[m] communicates with a reservoir 325 via an ink supply port 326. The reservoir 325 communicates with the ink cartridge 120 corresponding to the ejection portion D[m] via an ink intake port 327. The piezoelectric element PZ[m] includes an upper electrode Zu[m], a lower electrode Zd[m], and a piezoelectric body Zm[m] provided between the upper electrode Zu[m] and the lower electrode Zd[m]. The lower electrode Zd[m] is electrically coupled to a power supply line LD set to a predetermined potential VBS. When the supply drive signal Vin[m] is supplied to the upper electrode Zu[m] and a voltage is applied between the upper electrode Zu[m] and the lower electrode Zd[m], the piezoelectric element PZ[m] is displaced in the Z1 direction and the Z2 direction in correspondence with the applied voltage. As a result, the piezoelectric element PZ[m] vibrates. The lower electrode Zd[m] is joined to the vibration plate 321. Therefore, when the piezoelectric element PZ[m] is driven by the supply drive signal Vin[m] and vibrates, the vibration plate 321 also vibrates. The vibration of the vibration plate 321 changes the volume of the cavity CV[m] and the pressure in the cavity CV[m], and the ink filled in the cavity CV[m] is ejected from the nozzle N[m].

### A.2. Configuration and Operation of Head Unit 3

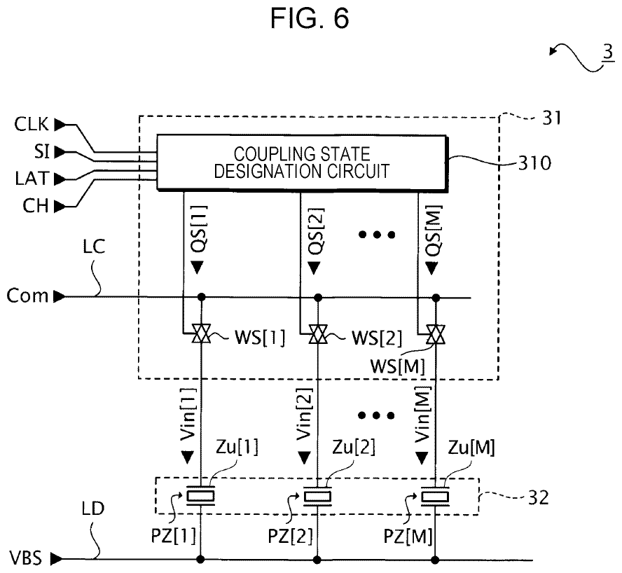

Hereinafter, an example of a configuration and an operation of the head unit 3 will be described with reference to FIGS. 6 to 8.

FIG. 6 is a block diagram illustrating an example of the configuration of the head unit 3.

As illustrated in FIG. 6, the head unit 3 includes the supply circuit 31 and the head portion 32. In addition, the head unit 3 includes a wiring LC to which the drive signal Com is supplied from the drive signal generation unit 4.

As illustrated in FIG. 6, the supply circuit 31 is provided with M switches WS[1] to WS[M] corresponding to the M ejection portions D[l] to D[M] in a one-to-one basis, and a coupling state designation circuit 310 that designates a coupling state of each switch.

The coupling state designation circuit 310 generates a coupling state designation signal QS[m] that designates ON or OFF of the switch WS[m] based on at least a part of the designation signal SI, a latch signal LAT, a change signal CH, and a clock signal CLK supplied from the print control unit 2.

The switch WS[m] switches between conduction and non-conduction between the wiring LC and the upper electrode Zu[m] of the piezoelectric element PZ[m] provided in the ejection portion D[m], based on the coupling state designation signal QS[m]. In the present embodiment, the switch WS[m] is turned on when the coupling state designation signal QS[m] is at a high level, and is turned off when the coupling state designation signal QS[m] is at a low level. When the switch WS[m] is turned on, the drive signal Com supplied to the wiring LC is supplied to the upper electrode Zu[m] of the ejection portion D[m] as the supply drive signal Vin[m].

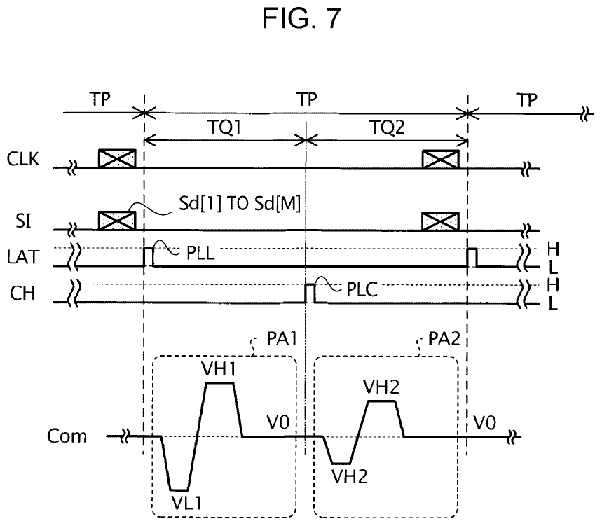

FIG. 7 is a timing chart illustrating an example of various signals such as the drive signal Com supplied to the head unit 3.

As illustrated in FIG. 7, when the ink jet printer 1 executes the print process, one or a plurality of unit periods TP are set as an operation period of the ink jet printer 1. In the present embodiment, the ink jet printer 1 can drive each ejection portion D[m] for the print process in each unit period TP.

As illustrated in FIG. 7, the print control unit 2 outputs the latch signal LAT having a pulse PLL.

Accordingly, the print control unit 2 defines the unit period TP as a period from the rise of the pulse PLL to the rise of the next pulse PLL. In addition, the print control unit 2 outputs the change signal CH having a pulse PLC in the unit period TP. The print control unit 2 divides the unit period TP into a drive period TQ1 from the rise of the pulse PLL to the rise of the pulse PLC and a drive period TQ2 from the rise of the pulse PLC to the rise of the pulse PLL.

As illustrated in FIG. 7, the designation signal SI includes M individual designation signals Sd[1] to Sd[M] corresponding to the M ejection portions D[l] to D[M] in a one-to-one basis. The individual designation signal Sd[m] designates an aspect of driving the ejection portion D[m] in each unit period TP when the ink jet printer 1 executes the print process. The print control unit 2 supplies the designation signal SI including the M individual designation signals Sd[1] to Sd[M] to the coupling state designation circuit 310 in synchronization with the clock signal CLK prior to each unit period TP. The coupling state designation circuit 310 generates the coupling state designation signal QS[m] based on the individual designation signal Sd[m] in the unit period TP.

Note that in the present embodiment, it is assumed that the ejection portion D[m] can form any dot among a large dot formed of the ink in an ink amount ξ1, a medium dot formed of the ink in an ink amount ξ2 smaller than the ink amount ξ1, and a small dot formed of the ink in an ink amount ξ3 smaller than the ink amount ξ2 in the unit period TP in which the print process is executed.

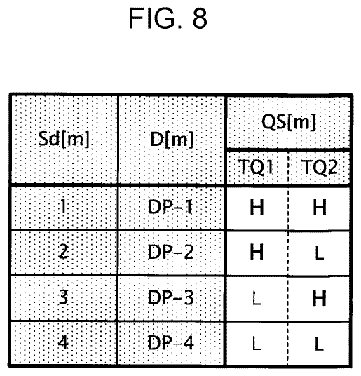

FIG. 8 is an explanatory view illustrating an example of an individual designation signal Sd[m].

As illustrated in FIG. 8, in the present embodiment, the individual designation signal Sd[m] can take any one value among four values, a value of “1” that designates the ejection portion D[m] as a large dot forming ejection portion DP-1, a value of “2” that designates the ejection portion D[m] as a medium dot forming ejection portion DP-2, a value of “3” that designates the ejection portion D[m] as a small dot forming ejection portion DP-3, and a value of “4” that designates the ejection portion D[m] as a dot non-forming ejection portion DP-4 in the unit period TP in which the print process is executed.

Here, the large dot forming ejection portion DP-1 is an ejection portion D that forms the large dot in the unit period TP. In addition, the medium dot forming ejection portion DP-2 is an ejection portion D that forms the medium dot in the unit period TP. In addition, the small dot forming ejection portion DP-3 is an ejection portion D that forms the small dot in the unit period TP. In addition, the dot non-forming ejection portion DP-4 is an ejection portion D that does not form the dot in the unit period TP.

The description will now return to FIG. 7.

As illustrated in FIG. 7, in the present embodiment, the drive signal Com has a waveform PA1 provided in the drive period TQ1 and a waveform PA2 provided in the drive period TQ2.

Among these, the waveform PA1 is a waveform that returns to the potential V0 from the potential V0 via a potential VL1 lower than the potential V0 and a potential VH1 higher than the potential V0. When the supply drive signal Vin[m] having the waveform PA1 is supplied to the ejection portion D[m], the waveform PA1 is determined such that the ink corresponding to an ink amount φ1 is ejected from the ejection portion D[m]. In addition, the waveform PA2 is a waveform that returns to the potential V0 from the potential V0 via a potential VL2 lower than the potential V0 and a potential VH2 higher than the potential V0. When the supply drive signal Vin[m] having the waveform PA2 is supplied to the ejection portion D[m], the waveform PA2 is determined such that the ink corresponding to an ink amount φ2 is ejected from the ejection portion D[m]. Note that in the present embodiment, it is assumed that the ink amount ξ1 corresponds to the total amount of the ink amount φ1 and the ink amount φ2, the ink amount ξ2 corresponds to the ink amount φ1, and the ink amount ξ3 corresponds to the ink amount φ2.

In addition, in the present embodiment, as an example, it is assumed that when the potential of the supply drive signal Vin[m] supplied to the ejection portion D[m] is high, the volume of the cavity CV[m] provided in the ejection portion D[m] is small as compared with a case of a low potential. Therefore, when the ejection portion D[m] is driven by the supply drive signal Vin[m] having the waveform PA1 or the like, the potential of the supply drive signal Vin[m] changes from a low potential to a high potential, and thus the ink in the ejection portion D[m] is ejected from the nozzle N[m].

As illustrated in FIG. 8, when the individual designation signal Sd[m] indicates the value “1” that designates the ejection portion D[m] as the large dot forming ejection portion DP-1 in the unit period TP, the coupling state designation circuit 310 sets the coupling state designation signal QS[m] to a high level in the drive period TQ1 and the drive period TQ2. In this case, the switch WS[m] is turned on in the drive period TQ1 and the drive period TQ2. Therefore, the ejection portion D[m] is driven by the supply drive signal Vin[m] having the waveform PA1 and the waveform PA2 in the unit period TP, and ejects the ink in the ink amount 1 corresponding to the large dot.

In addition, when the individual designation signal Sd[m] indicates the value “2” that designates the ejection portion D[m] as the medium dot forming ejection portion DP-2 in the unit period TP, the coupling state designation circuit 310 sets the coupling state designation signal QS[m] to a high level in the drive period TQ1. In this case, the switch WS[m] is turned on in the drive period TQ1. Therefore, the ejection portion D[m] is driven by the supply drive signal Vin[m] having the waveform PA1 in the unit period TP, and ejects the ink in the ink amount 2 corresponding to the medium dot.

In addition, when the individual designation signal Sd[m] indicates the value “3” that designates the ejection portion D[m] as the small dot forming ejection portion DP-3 in the unit period TP, the coupling state designation circuit 310 sets the coupling state designation signal QS[m] to a high level in the drive period TQ2. In this case, the switch WS[m] is turned on in the drive period TQ2. Therefore, the ejection portion D[m] is driven by the supply drive signal Vin[m] having the waveform PA2 in the unit period TP, and ejects the ink in the ink amount 3 corresponding to the small dot.

In addition, when the individual designation signal Sd[m] indicates the value “4” that designates the ejection portion D[m] as the dot non-forming ejection portion DP-4 in the unit period TP, the coupling state designation circuit 310 sets the coupling state designation signal QS[m] to a low level over the unit period TP. In this case, the switch WS[m] is turned off over the unit period TP. Therefore, the ejection portion D[m] is not driven by the supply drive signal Vin[m] and does not eject the ink in the unit period TP.

### A. 3. Configuration of Drive Signal Generation Circuit 40

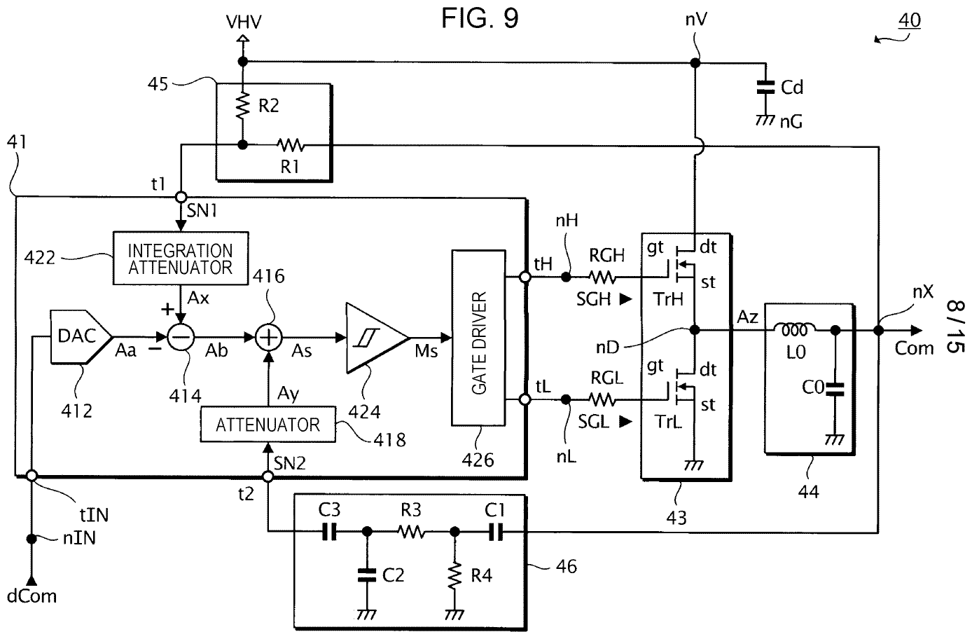

Hereinafter, an example of the configuration of the drive signal generation circuit 40 provided in the drive signal generation unit 4 will be described with reference to FIG. 9.

FIG. 9 is a block diagram illustrating an example of a circuit configuration of the drive signal generation circuit 40.

As illustrated in FIG. 9, the drive signal generation circuit 40 includes an integrated circuit 41, an amplification circuit 43, a smoothing circuit 44, a pull-up circuit 45, a filter circuit 46, and an electrolytic capacitor Cd, and is a class D amplification circuit that generates the drive signal Com based on the waveform designation signal dCom.

The integrated circuit 41 is, for example, a large scale integration (LSI), and generates a gate signal SGH and a gate signal SGL based on the waveform designation signal dCom supplied to a terminal tIN via a node nIN. The integrated circuit 41 includes an analog conversion circuit 412, a subtractor 414, an adder 416, an attenuator 418, an integration attenuator 422, a comparator 424, and a gate driver 426.

The analog conversion circuit 412 is a digital to analog converter (DAC) and converts the digital waveform designation signal dCom into an analog signal Aa. Note that a voltage amplitude of the signal Aa is, for example, substantially 0 to 2 volts, and the voltage amplified by substantially 20 times is the drive signal Com. That is, the signal Aa is a signal before amplification of the drive signal Com.

The integration attenuator 422 outputs a signal Ax obtained by attenuating and then integrating a signal SN1 input to a terminal t1 to be described later.

The subtractor 414 outputs a signal Ab indicating a potential obtained by subtracting a potential of the signal Aa from a potential of the signal Ax.

The attenuator 418 outputs a signal Ay obtained by attenuating a high-frequency component of a signal SN2 input to a terminal t2 to be described later.

The adder 416 outputs a signal As indicating a potential obtained by adding a potential of the signal Ab and a potential of the signal Ay.

The comparator 424 outputs a modulated signal Ms obtained by pulse-modulating the signal As. Specifically, the comparator 424 outputs the modulated signal Ms of which a level becomes a high level when a voltage is equal to or greater than a threshold voltage Vth1 while the voltage of the signal As rises, and becomes a low level when the voltage falls below a threshold voltage Vth2 while the voltage of the signal As falls. Note that the threshold voltage Vth1 and the threshold voltage Vth2 are set to have a relationship of “Vth1>Vth2”.

Note that a power supply voltage of a circuit from the analog conversion circuit 412 to the comparator 424 is, for example, a low voltage such as 3.3 volts. On the other hand, the drive signal Com has a large amplitude and may exceed, for example, 40 volts. Therefore, in the integration attenuator 422, the signal SN1 having an amplitude corresponding to the drive signal Com is attenuated, and an amplitude range of the signal Ax is matched with an amplitude range of the signal in the circuit from the analog conversion circuit 412 to the comparator 424.

In the present embodiment, a digital signal is exemplified and described as the waveform designation signal dCom, but the waveform designation signal dCom may be any signal that defines a target value for generating the drive signal Com, and for example, the analog signal Aa may be used as the waveform designation signal dCom. When the signal Aa is the waveform designation signal dCom, the integrated circuit 41 may be configured without including the analog conversion circuit 412.

The gate driver 426 outputs the gate signal SGH obtained by converting the modulated signal Ms into a specific amplitude to the node nH via a terminal tH. Further, the gate driver 426 outputs the gate signal SGL obtained by converting a signal obtained by inverting a logic level of the modulated signal Ms to a specific amplitude to a node nL via a terminal tL.

The amplification circuit 43 includes, for example, a transistor TrH and a transistor TrL, and generates an amplified signal Az which is a signal obtained by amplifying the modulated signal Ms based on the gate signal SGH and the gate signal SGL output from the integrated circuit 41. Note that in the present embodiment, as an example, it is assumed that the transistor TrH and the transistor TrL are field effect transistors. More specifically, in the present embodiment, it is assumed that N-channel type metal-oxide-semiconductor field-effect transistors (MOSFETs) are adopted as the transistor TrH and the transistor TrL.

The gate signal SGH output from the gate driver 426 to the terminal tH is input to a gate electrode gt of the transistor TrH via the node nH and a resistor RGH. In addition, the gate signal SGL output from the gate driver 426 to the terminal tL is input to a gate electrode gt of the transistor TrL via the node nL and a resistor RGL. The logic levels of the gate signal SGH and the gate signal SGL are in a mutually exclusive relationship with each other. Here, the term “mutually exclusive relationship” means that a signal level of the gate signal SGH supplied to the gate electrode gt of the transistor TrH and a signal level of the gate signal SGL supplied to the gate electrode gt of the transistor TrL do not become high level at the same time, in other words, the transistor TrH and the transistor TrL are not turned on at the same time. The transistor TrH is turned on when a potential of the gate electrode gt of the transistor TrH is at a high level, and is turned off when the potential of the gate electrode gt of the transistor TrH is at a low level. The transistor TrL is turned on when a potential of the gate electrode gt of the transistor TrL is at a high level, and is turned off when the potential of the gate electrode gt of the transistor TrL is at a low level.

In the transistor TrH, a drain electrode dt is electrically coupled to a node nV set to a power supply potential VHV on a high potential side, and a source electrode st is electrically coupled to a node nD. In addition, in the transistor TrL, a source electrode st is electrically coupled to a node nG set to a ground potential, and a drain electrode dt is electrically coupled to the node nD. Note that the source electrode of the transistor TrL may be electrically coupled to the power supply line LD set to a potential VBS.

As described above, the transistor TrH is turned on when the gate signal SGH supplied to the gate electrode gt is at a high level, and is turned off when the gate signal SGH is at a low level. The transistor TrL is turned on when the gate signal SGL supplied to the gate electrode gt is at a high level, and is turned off when the gate signal SGL is at a low level. Therefore, the amplified signal Az obtained by amplifying the modulated signal Ms is output to the node nD that electrically couples the source electrode st of the transistor TrH and the drain electrode dt of the transistor TrL.

The electrolytic capacitor Cd is coupled to the node nV to which the power supply potential VHV is supplied. One end of the electrolytic capacitor Cd is electrically coupled to the node nV, and the other end is electrically coupled to the node nG set to the ground potential. In the present embodiment, the electrolytic capacitor Cd is, for example, a large-capacity aluminum electrolytic capacitor, and suppresses a potential fluctuation at the node nV to stabilize the power supply potential VHV.

The smoothing circuit 44 is a low pass filter (LPF), and smooths the amplified signal Az to generate the drive signal Com. The smoothing circuit 44 includes an inductor L0 and a capacitor C0. One end of the inductor L0 is electrically coupled to the node nD, and the other end is electrically coupled to a node nX. One end of the capacitor C0 is electrically coupled to the node nX, and the other end is electrically coupled to the node nG set to the ground potential.

The pull-up circuit 45 feeds back the signal SN1 obtained by pulling up the drive signal Com output to the node nX to the terminal t1. The pull-up circuit 45 includes a resistor R1 having one end electrically coupled to the node nX and the other end electrically coupled to the terminal t1, and a resistor R2 having one end electrically coupled to the terminal t1 and the other end electrically coupled to a node nV set to the power supply potential VHV.

The filter circuit 46 is a band pass filter (BPF), and feeds back the signal SN2 in which a DC component is cut from a frequency component in a predetermined band of the drive signal Com to the terminal t2. The filter circuit 46 includes a resistor R3, a capacitor C1 of which one end is electrically coupled to the node nX and the other end is electrically coupled to one end of the resistor R3, a resistor R4 of which one end is electrically coupled to the one end of the resistor R3 and the other end is electrically coupled to the node nG set to the ground potential, a capacitor C2 of which one end is electrically coupled to the other end of the resistor R3 and the other end is electrically coupled to the node nG set to the ground potential, and a capacitor C3 of which one end is electrically coupled to the other end of the resistor R3 and the other end is electrically coupled to the terminal t2. Among these, the capacitor C1 and the resistor R4 function as a high pass filter (HPF) that allows a high-frequency component, which is equal to or higher than a cutoff frequency, in the drive signal Com to pass. In addition, the resistor R3 and the capacitor C2 function as a low pass filter (LPF) that allows a low frequency component, which is equal to or lower than the cutoff frequency, in the drive signal Com to pass. In the present embodiment, in the filter circuit 46, the cutoff frequency of the HPF is set to be lower than the cutoff frequency of the LPF. Therefore, the filter circuit 46 allows a frequency component of a predetermined band, which is equal to or higher than the cutoff frequency of the HPF and is equal to or lower than the cutoff frequency of the LPF, in the drive signal Com to pass. Further, since the filter circuit 46 includes the capacitor C3, the filter circuit 46 feeds back a signal, from which a DC component is cut, from a signal of a frequency component in a predetermined band that has passed through the HPF and the LPF in the drive signal Com to the terminal t2.

As described above, the drive signal generation circuit 40 generates the drive signal Com by smoothing the amplified signal Az at the node nD by the smoothing circuit 44. The drive signal Com is integrated and subtracted by the integration attenuator 422 and then fed back to the subtractor 414. Therefore, self-excited oscillation occurs at a frequency determined by delay in the smoothing circuit 44, delay in the integration attenuator 422, and a feedback transfer function. However, since a delay amount of a feedback path via the terminal t1 is large, the frequency of self-excited oscillation cannot be increased to such an extent that accuracy of the waveform of the drive signal Com can be sufficiently secured only by the feedback via the terminal t1. In contrast, in the present embodiment, since a path for feeding back the high-frequency component of the drive signal Com is provided via the terminal t2 in addition to the path via the terminal t1, the delay of the feedback in the entire drive signal generation circuit 40 can be reduced. That is, in the present embodiment, since the frequency of the signal As obtained by adding the signal Ay, which is the high-frequency component of the drive signal Com, to the signal Ab can be made higher as compared with a case where the path via the terminal t2 does not exist, the accuracy of the drive signal Com can be sufficiently secured.

Note that in the present embodiment, the electrolytic capacitor Cd included in the drive signal generation circuit 40 of the drive control circuit 50 is an example of an “electronic component”.

### A. 4. Configuration of Drive Control Unit 5 and Wireless Communication Unit 6

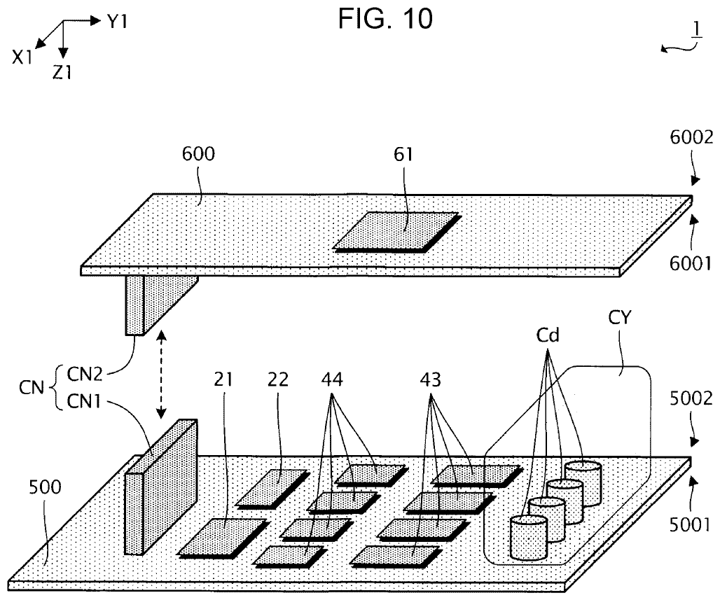

Hereinafter, the configuration of the drive control unit 5 and the wireless communication unit 6 will be described with reference to FIGS. 10 to 12.

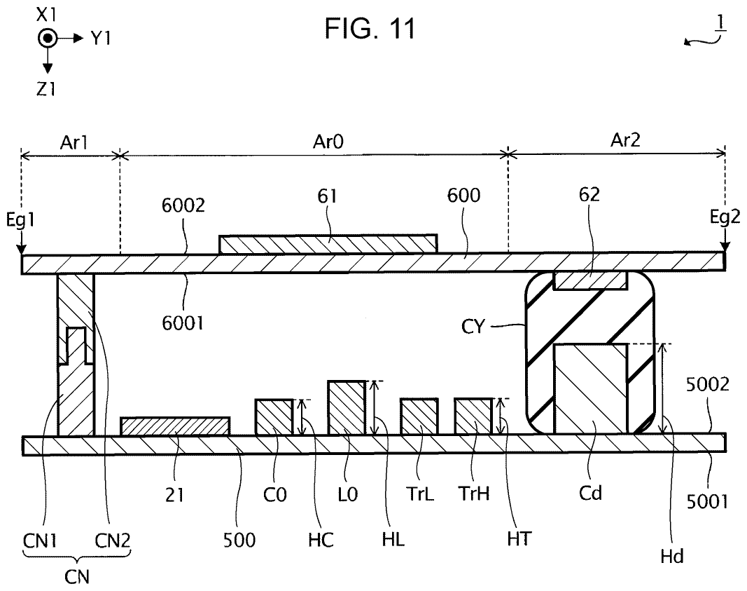

FIG. 10 is an exploded perspective view illustrating an example of a configuration including the drive control unit 5 and the wireless communication unit 6. FIG. 11 is a cross-sectional view illustrating an example of the configuration including the drive control unit 5 and the wireless communication unit 6.

As illustrated in FIGS. 10 and 11, the ink jet printer 1 includes the drive control unit 5, the wireless communication unit 6, a substrate-to-substrate connector CN, and a support column CY.

As described above, the wireless communication unit 6 includes the communication substrate 600, the antenna 61 provided on the communication substrate 600, and the communication control circuit 62.

The communication substrate 600 has a lower surface 6001 (an example of a “first surface”) facing the Z1 direction and an upper surface 6002 (an example of a “second surface”) facing the Z2 direction, which is a surface opposite to the lower surface 6001.

The antenna 61 is an element for transmitting and receiving a signal by wireless communication, and is provided on the upper surface 6002.

The communication control circuit 62 (an example of a “communication circuit”) is a circuit for controlling execution of wireless communication using the antenna 61, and is provided on the lower surface 6001.

As described above, the drive control unit 5 includes the control substrate 500 and the drive control circuit 50 provided on the control substrate 500.

The control substrate 500 has a lower surface 5001 facing the Z1 direction and an upper surface 5002 facing the Z2 direction, which is a surface opposite to the lower surface 5001. In the present embodiment, the upper surface 5002 of the control substrate 500 and the lower surface 6001 of the communication substrate 600 face each other.

As described above, the drive control circuit 50 includes the print control circuit 21, the storage circuit 22, and the drive signal generation circuit 40. The drive signal generation circuit 40 includes an amplification circuit 43 including the transistor TrH and the transistor TrL, the smoothing circuit 44 including the inductor L0 and the capacitor C0, and the electrolytic capacitor Cd. In the present embodiment, the drive control circuit 50 is provided on the upper surface 5002.

Note that in the present embodiment, it is assumed that a height Hd of the electrolytic capacitor Cd in the Z-axis direction is higher than a height HT of the transistor TrH and the transistor TrL in the Z-axis direction, a height HL of the inductor L0 in the Z-axis direction, and a height HC of the capacitor C0 in the Z-axis direction. In the present embodiment, it is assumed that the electrolytic capacitor Cd has a larger volume as compared with other electronic components that constitute the drive control circuit 50.

The substrate-to-substrate connector CN (an example of a “coupling component”) couples the control substrate 500 and the communication substrate 600. Specifically, the substrate-to-substrate connector CN includes a connector component CN1 fixed to the upper surface 5002 of the control substrate 500, and a connector component CN2 fixed to the lower surface 6001 of the communication substrate 600 and configured to be fitted with the connector component CN1. The connector component CN1 is, for example, a male connector, and the connector component CN2 is, for example, a female connector. The substrate-to-substrate connector CN couples the control substrate 500 and the communication substrate 600 by fitting the connector component CN1 and the connector component CN2, and enables transmission of signals between the control substrate 500 and the communication substrate 600.

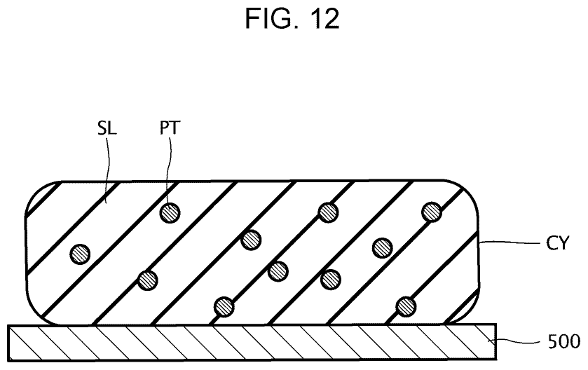

FIG. 12 is a schematic view illustrating an example of the support column CY.

As illustrated in FIG. 12, the support column CY includes a base material SL and heat conductive particles PT.

The base material SL is a clay-like substance having an electrical insulation property. As the base material SL, for example, clay formed of silicone can be adopted.

The heat conductive particles PT are particles formed of a substance having a high heat conductivity such as diamond, gold, silver, and copper, and are dispersed in the base material SL. Note that in the present embodiment, the heat conductive particles PT are provided such that the diameter of the heat conductive particles PT is sufficiently smaller than a distance between wirings included in the drive control circuit 50. Therefore, in the present embodiment, even when the conductive substance is adopted as the heat conductive particles PT, the support column CY can suppress electrical coupling between two components in the drive control circuit 50, and can maintain the electrical insulation property of the entire support column CY.

As illustrated in FIGS. 10 and 11, the support column CY is provided between the upper surface 5002 of the control substrate 500 and the lower surface 6001 of the communication substrate 600 to support the communication substrate 600 with respect to the control substrate 500.

Specifically, in the present embodiment, the support column CY is provided to cover a part or the entirety of the electrolytic capacitor Cd and a part or the entirety of the communication control circuit 62 when the drive control unit 5 and the wireless communication unit 6 are viewed in a plan view in the Z1 direction. That is, in the present embodiment, the support column CY is provided to overlap a part or the entirety of the electrolytic capacitor Cd and a part or the entirety of the communication control circuit 62 when the drive control unit 5 and the wireless communication unit 6 are viewed in a plan view in the Z1 direction.

Meanwhile, the present disclosure is not limited to such an aspect. When the drive control unit 5 and the wireless communication unit 6 are viewed in plan view in the Z1 direction, the support column CY may be provided not to overlap the communication control circuit 62. In addition, when the drive control unit 5 and the wireless communication unit 6 are viewed in plan view in the Z1 direction, the support column CY may be provided not to overlap the electrolytic capacitor Cd.

In the present embodiment, the communication substrate 600 includes an end portion region Ar1, an end portion region Ar2, and an intermediate region Ar0. Here, the end portion region Ar1 (an example of the “first region”) is a region including an end portion Eg1 of the communication substrate 600 in the Y2 direction when the communication substrate 600 is viewed in plan view in the Z1 direction, and is a region in the vicinity of the end portion Eg1. The end portion region Ar2 (an example of the “second region”) is a region including an end portion Eg2 of the communication substrate 600 in the Y1 direction when the communication substrate 600 is viewed in plan view in the Z1 direction, and is a region in the vicinity of the end portion Eg2. The intermediate region Ar0 is a region between the end portion region Ar1 and the end portion region Ar2 when the communication substrate 600 is viewed in plan view in the Z1 direction.

In the present embodiment, the connector component CN2 is fixed to the lower surface 6001 in the end portion region Ar1 of the communication substrate 600, and the support column CY is provided to support the lower surface 6001 in the end portion region Ar2 of the communication substrate 600.

### A. 5. Comparative Example

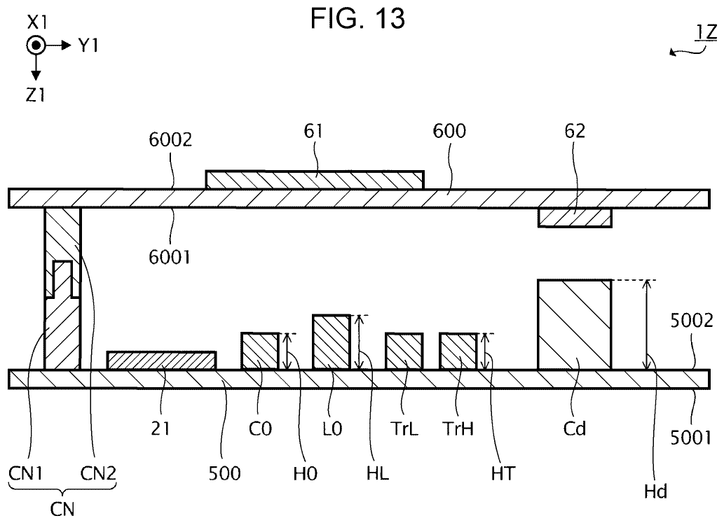

Hereinafter, to clarify the effect of the present embodiment, an ink jet printer 1Z according to a comparative example will be described with reference to FIG. 13.

FIG. 13 is a cross-sectional view illustrating an example of a configuration of the ink jet printer 1Z according to the comparative example.

As illustrated in FIG. 13, the ink jet printer 1Z according to the comparative example is configured in the same manner as the ink jet printer 1 according to the embodiment except that the support column CY is not provided.

In the comparative example, vibration occurs in the ink jet printer 1Z due to transport of the recording paper PP by the transport unit 9, transport of the carriage 110 by the transport unit 9, carrying of the ink jet printer 1Z by a user of the ink jet printer 1Z, or the like. When vibration occurs in the ink jet printer 1Z, a slight change may occur in a relative position between the control substrate 500 and the communication substrate 600, and a slight change may occur in a relative posture between the control substrate 500 and the communication substrate 600. When the change occurs in the relative position or posture of the control substrate 500 and the communication substrate 600, a load is applied between the substrate-to-substrate connector CN and the control substrate 500, and between the substrate-to-substrate connector CN and the communication substrate 600, and so-called fretting in which at least a part of a surface of the substrate-to-substrate connector CN, the control substrate 500, and the communication substrate 600 is damaged may occur. When surface damage occurs in at least a part of the substrate-to-substrate connector CN, the control substrate 500, and the communication substrate 600, a fine fragment may be scraped from these components. When the fragment generated in the surface damage is oxidized, and the oxidized fragment comes into contact with a joint portion between the substrate-to-substrate connector CN and the substrate (the control substrate 500 or the communication substrate 600), a contact failure may be induced between the substrate-to-substrate connector CN and the substrate, or when the oxidized fragment comes into contact with a circuit such as the drive control circuit 50, so-called fretting corrosion in which a contact failure is induced in the circuit may occur.

On the other hand, in the present embodiment, the communication substrate 600 is supported by the support column CY in addition to being coupled to the control substrate 500 by the substrate-to-substrate connector CN. Therefore, according to the present embodiment, as compared with the comparative example, when vibration occurs in the ink jet printer 1, the degree of change in the relative position and posture between the control substrate 500 and the communication substrate 600 can be reduced. Therefore, according to the present embodiment, as compared with the comparative example, the possibility that a damage occurs on at least a part of the surfaces of the substrate-to-substrate connector CN, the control substrate 500, and the communication substrate 600 can be reduced, and the possibility of occurrence of fragments due to the surface damage in these components can be reduced. Therefore, according to the present embodiment, as compared with the comparative example, the contact failure between the substrate-to-substrate connector CN and the substrate (control substrate 500 or communication substrate 600) due to the fragments generated by the surface damage, a contact failure inside the circuit of the drive control circuit 50 and the like due to the fragments generated by the surface damage, or the like can be suppressed. That is, according to the present embodiment, the degree of damage due to fretting can be reduced as compared with the comparative example, and thus the possibility of occurrence of a problem due to the fretting corrosion can be reduced.

### A. 6. Summary of First Embodiment

As described above, according to the present embodiment, since the communication substrate 600 is supported by the support column CY in addition to being coupled to the control substrate 500 by the substrate-to-substrate connector CN, as compared with an aspect in which the support column CY is not provided, the degree of change in the relative position and posture between the control substrate 500 and the communication substrate 600 can be reduced, and the possibility of occurrence of the fragments due to the surface damage in at least a part of the substrate-to-substrate connector CN, the control substrate 500, and the communication substrate 600 can be reduced. Therefore, according to the present embodiment, the possibility of occurrence of a problem due to the fretting corrosion can be reduced as compared with the aspect in which the support column CY is not provided.

Further, according to the present embodiment, the support column CY is provided to cover the electrolytic capacitor Cd, and thus the height of the support column CY, which is clay-like and has low rigidity, in the Z-axis direction is reduced, and the communication substrate 600 can be more stably supported on the control substrate 500 as compared with an aspect in which the support column CY is disposed directly on the upper surface 5002 of the control substrate 500 not to cover the electrolytic capacitor Cd.

Further, according to the present embodiment, the support column CY is provided to cover the communication control circuit 62, and thus the height of the support column CY in the Z-axis direction is reduced, and the communication substrate 600 can be more stably supported by the control substrate 500 as compared with an aspect in which the support column CY is provided not to cover the communication control circuit 62 and directly supports a lower surface 6001 of the communication substrate 600.

Further, according to the present embodiment, the antenna 61 is provided on the upper surface 6002. Therefore, according to the present embodiment, as compared with the aspect in which the antenna 61 is provided on the lower surface 6001, the possibility that transmission and reception of a signal in the antenna 61 is inhibited by the communication substrate 600 or the support column CY can be reduced.

Further, according to the present embodiment, the communication substrate 600 is provided separately from the control substrate 500. Therefore, according to the present embodiment, the communication substrate 600 can be easily detached from the ink jet printer 1 as compared with an aspect in which the communication substrate 600 and the control substrate 500 are provided as a single substrate. Therefore, according to the present embodiment, for example, when the ink jet printer 1 is discarded, the cost related to a reuse of the communication substrate 600 can be reduced, and an environmental load of the ink jet printer 1 can be reduced. Further, according to the present embodiment, for example, when the communication method used by the ink jet printer 1 is changed, the communication substrate 600 corresponding to a scheduled communication method used by the ink jet printer 1 can be easily replaced, and the ink jet printer 1 can be used in various environments.

Note that it is preferable that the color of the support column CY is different from at least one of a color of the control substrate 500 and a color of the communication substrate 600. In the present embodiment, it is assumed that the support column CY has a color different from that of the control substrate 500 and a color different from that of the communication substrate 600.

Further, according to the present embodiment, since the support column CY is in contact with the control substrate 500 and the communication substrate 600, heat generated in the drive control circuit 50 can be dissipated via the support column CY and the communication substrate 600.

Further, according to the present embodiment, since the substrate-to-substrate connector CN is fixed to the communication substrate 600 in the end portion region Ar1, and the support column CY supports the communication substrate 600 in the end portion region Ar2, the communication substrate 600 can be more stably supported with respect to the control substrate 500 as compared with an aspect in which one or both of the substrate-to-substrate connector CN and the support column CY are provided in the intermediate region Ar0.

### B. Second Embodiment

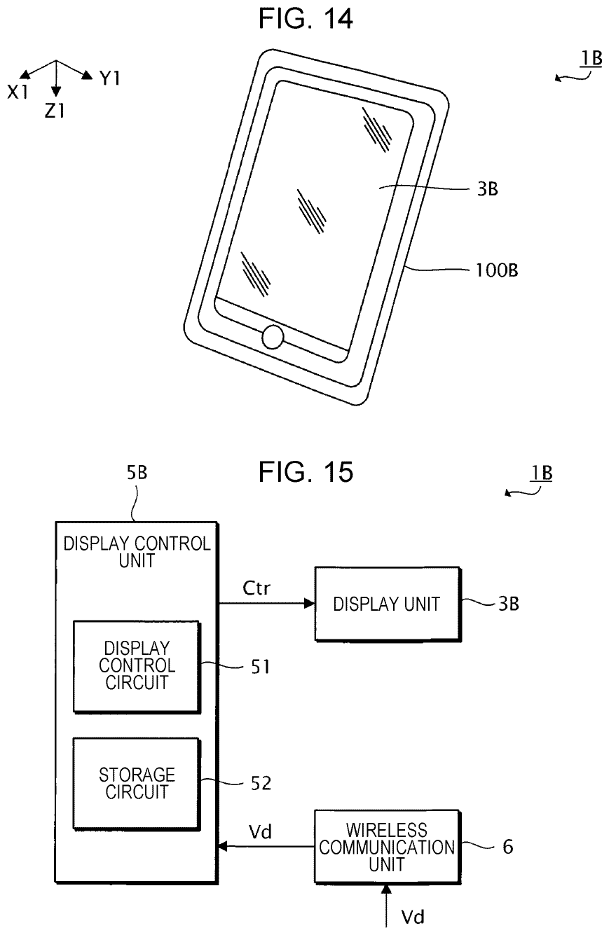

In a second embodiment, an electronic device will be described with reference to FIGS. 14 to 16 by using a smartphone 1B as an example. Note that in each embodiment illustrated below, elements whose operations and functions are similar to those of the first embodiment will be denoted by the same reference numerals used in the description of the first embodiment and detailed description thereof will be omitted as appropriate.

FIG. 14 is an external perspective view illustrating an example of an external appearance of the smartphone 1B.

As illustrated in FIG. 14, the smartphone 1B is an electronic device that can be carried by a user of the smartphone 1B, and includes a housing 100B and a display unit 3B.

FIG. 15 is a functional block diagram illustrating an example of a configuration of the smartphone 1B.

As illustrated in FIG. 15, the smartphone 1B is supplied with video data Vd indicating a video to be displayed by the smartphone 1B from a host computer such as a personal computer or a digital camera. The smartphone 1B causes the display unit 3B to display the video indicated by the video data Vd supplied from the host computer.

As illustrated in FIG. 15, the smartphone 1B includes a wireless communication unit 6 that acquires the video data Vd by wireless communication, a display control unit 5B that generates a display control signal Ctr based on the video data Vd, and a display unit 3B that displays the video indicated by the video data Vd based on the display control signal Ctr.

Note that in the present embodiment, the smartphone 1B is an example of an “electronic device”, the display unit 3B is an example of a “drive device”, the display control signal Ctr is an example of a “control signal”, and the video data Vd is an example of “instruction information”.

The display control unit 5B includes a display control circuit 51 that generates the display control signal Ctr based on the video data Vd supplied from the wireless communication unit 6, and a storage circuit 52 that stores various pieces of information such as a control program of the smartphone 1B. Hereinafter, a circuit including the display control circuit 51 and the storage circuit 52 is referred to as a drive control circuit 50B.

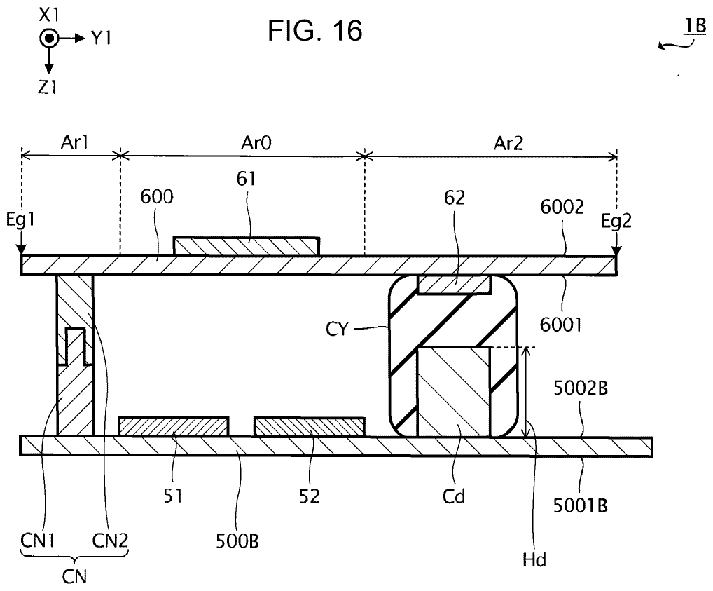

FIG. 16 is a cross-sectional view illustrating an example of a configuration of the smartphone 1B including the display control unit 5B and the wireless communication unit 6.

As illustrated in FIG. 16, the smartphone 1B includes the display control unit 5B, the wireless communication unit 6, a substrate-to-substrate connector CN, and a support column CY.

The wireless communication unit 6 includes a communication substrate 600, an antenna 61, and a communication control circuit 62 provided on the communication substrate 600 as in the first embodiment.

The display control unit 5B includes a control substrate 500B and the drive control circuit 50B provided on the control substrate 500B.

The control substrate 500B (another example of the “first substrate”) includes a lower surface 5001B facing the Z1 direction and an upper surface 5002B facing the Z2 direction, which is a surface opposite to the lower surface 5001B. In the present embodiment, the upper surface 5002B of the control substrate 500B and a lower surface 6001 of the communication substrate 600 face each other.

The drive control circuit 50B includes an electrolytic capacitor Cd in addition to the display control circuit 51 and the storage circuit 52 described above. In the present embodiment, the drive control circuit 50B is provided on the upper surface 5002B.

Note that in the present embodiment, it is assumed that a height Hd of the electrolytic capacitor Cd in the Z-axis direction is higher than the heights of the display control circuit 51 and the storage circuit 52 in the Z-axis direction. In the present embodiment, it is assumed that the electrolytic capacitor Cd has a larger volume as compared with other electronic components constituting the drive control circuit 50B. Note that in the present embodiment, the electrolytic capacitor Cd is an example of the “first electronic component”, and the communication control circuit 62 is an example of the “second electronic component”.

In the present embodiment, the substrate-to-substrate connector CN couples the control substrate 500B and the communication substrate 600. Specifically, in the present embodiment, a connector component CN1 included in the substrate-to-substrate connector CN is fixed to the upper surface 5002B of the control substrate 500B, and a connector component CN2 included in the substrate-to-substrate connector CN is fixed to the lower surface 6001 of the communication substrate 600. The substrate-to-substrate connector CN couples the control substrate 500B and the communication substrate 600 by fitting the connector component CN1 and the connector component CN2, and enables transmission of signals between the control substrate 500B and the communication substrate 600.

As described above, according to the present embodiment, since the communication substrate 600 is supported by the support column CY in addition to being coupled to the control substrate 500B by the substrate-to-substrate connector CN, as compared with an aspect in which the support column CY is not provided, the degree of change in the relative position and posture between the control substrate 500B and the communication substrate 600 can be reduced, and the possibility of occurrence of fragments due to the surface damage in at least a part of the substrate-to-substrate connector CN, the control substrate 500B, and the communication substrate 600 can be reduced. Therefore, according to the present embodiment, the possibility of occurrence of a problem due to the fretting corrosion can be reduced as compared with the aspect in which the support column CY is not provided.

Note that in the present embodiment, the communication substrate 600 may be a substrate having one side of 1 inch or less. Specifically, for example, the communication substrate 600 may be a Wi-Fi (registered trademark) chip having one side of 1 inch or less.

Further, also in the present embodiment, as in the first embodiment, the connector component CN2 is fixed to the lower surface 6001 in the end portion region Ar1 of the communication substrate 600, and the support column CY is provided to support the lower surface 6001 in the end portion region Ar2 of the communication substrate 600.

### C. Modification Example

Each aspect described above can be variously modified. A specific aspect of the modification will be described below. Two or more aspects selected in any manner from the following examples can be combined with each other as appropriate within a range not inconsistent with each other. Note that in the modification examples illustrated below, elements whose operations or functions are the same as those of the embodiments will be designated by the same reference numerals as those used in the above description, and the detailed description of each of the elements will be appropriately omitted.

### Modification Example 1

In the first embodiment and the second embodiment described above, an aspect in which the support column CY is provided to cover only the electrolytic capacitor Cd of the drive control circuit 50 or the drive control circuit 50B is described as an example, but the present disclosure is not limited to such an aspect. The support column CY may be provided to cover electronic components other than the electrolytic capacitor Cd in the drive control circuit 50 or the drive control circuit 50B. In this case, the support column CY may be provided to cover the electrolytic capacitor Cd, or may be provided not to cover the electrolytic capacitor Cd.

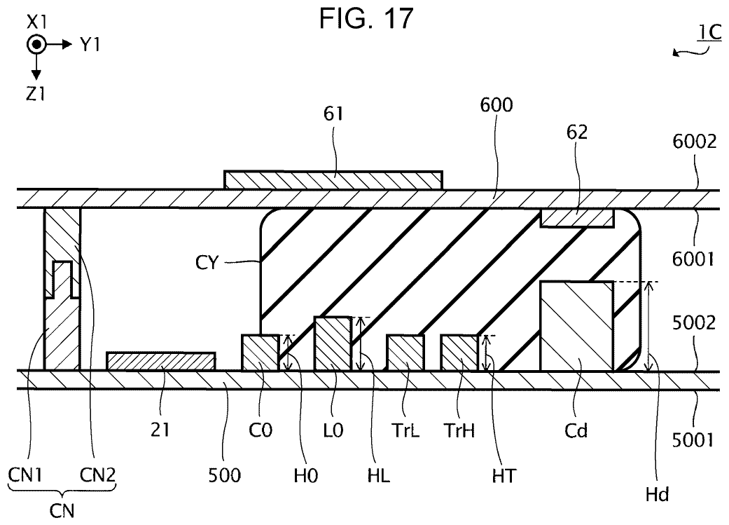

FIG. 17 is a cross-sectional view illustrating an example of a configuration of an ink jet printer 1C according to Modification Example 1.

As illustrated in FIG. 17, the ink jet printer 1C is configured in the same manner as the ink jet printer 1 according to the first embodiment except that the support column CY is provided to cover the transistor TrH, the transistor TrL, the inductor L0, and a part of the capacitor C0 in addition to the electrolytic capacitor Cd in a wide range.

According to the present modification example, since the support column CY stably supports the communication substrate 600, the change in the relative position and posture between the control substrate 500 and the communication substrate 600 in the ink jet printer 1C can be suppressed, and occurrence of a problem due to the fretting corrosion can be suppressed.

In addition, according to the present modification example, since the transistor TrH, the transistor TrL, and the inductor L0, which are electronic components that become high temperature when the drive signal generation circuit 40 generates the drive signal Com, are covered by the support column CY, these electronic components that become high temperature can be efficiently cooled as compared with an aspect in which the electronic components are not covered by the support column CY.

Note that in the present modification example, it is assumed that the inductor L0 covered with the support column CY includes a coil and a shield covering the coil. Therefore, according to the present modification example, the inductor L0 has a surface shape having less irregularities as compared with an aspect in which the inductor L0 does not include the shield, and thus the possibility that a gap is generated between the support column CY and the inductor L0 can be reduced, and a stable support of the communication substrate 600 by the support column CY can be realized. Further, according to the present modification example, as compared with the aspect in which the inductor L0 does not include the shield, separation between silicone clay included in the support column CY and the inductor L0 is facilitated, and reusability of the inductor L0 can be improved.

### Modification Example 2

In the first embodiment, the second embodiment, and Modification Example 1 described above, an aspect in which the control substrate 500 (or the control substrate 500B) and the communication substrate 600 are coupled by the substrate-to-substrate connector CN is exemplified and described, but the present disclosure is not limited to such an aspect. For example, the control substrate 500 (or the control substrate 500B) and the communication substrate 600 may be coupled by a pin header. Here, the pin header is another example of the “coupling component”, and includes an insertion pin member including a plurality of insertion pins formed of metal and a holding portion holding the plurality of insertion pins in a state of being insulated from each other, and a pin socket having a plurality of insertion holes provided corresponding to the plurality of insertion pins.

In the present modification example, a case in which the insertion pin member of the pin header is fixed to the lower surface 5001 of the control substrate 500, and the pin socket of the pin header is fixed to the upper surface 6002 of the communication substrate 600 is assumed. The pin header couples the control substrate 500 and the communication substrate 600 to each other by fitting the insertion pin member and the pin socket to each other and transmits a signal between the control substrate 500 and the communication substrate 600.

### Modification Example 3

In the first embodiment, the second embodiment, and Modification Examples 1 and 2 described above, an aspect in which the support column CY includes the heat conductive particles PT in addition to the base material SL formed of silicone clay is described as an example, but the present disclosure is not limited to such an aspect. The support column CY may be configured without including the heat conductive particles PT. For example, the support column CY may be silicone clay. In addition, for example, the support column CY may be formed of a clay-like substance having an electrical insulation property other than silicone clay.

### Modification Example 4

In the first embodiment, the second embodiment, and Modification Examples 1 to 3 described above, the ink jet printer and the smartphone are exemplified and described as the electronic device, but the present disclosure is not limited to such an aspect. The electronic device according to the present disclosure may be any electronic device including, for example, two or more circuit substrates, and may be an electronic device other than the ink jet printer and the smartphone, such as a digital camera, a projector, and the like. In this case, the first substrate may be a substrate provided in a main body of the electronic device, or the second substrate may be a substrate provided separately from the first substrate.

### D. Additional Notes

Aspects related to the above description are additionally noted below. Note that for easy understanding of each aspect, in the following description, reference numerals in the drawings are given in parentheses for convenience, but the present disclosure is not limited to the illustrated aspect.

### D. 1. Additional Note 1

Hereinafter, an ink jet printer 1 according to Additional Note 1 will be described.

### Additional Note 1-1

According to Additional Note 1-1, there is provided an ink jet printer 1 including: a head unit 3 that forms an image on recording paper PP based on a designation signal SI; a communication substrate 600 provided with a communication control circuit 62 that receives image data Img indicating the image by wireless communication; a control substrate 500 provided with a drive control circuit 50 that generates the designation signal SI based on the image data Img; and a substrate-to-substrate connector CN that couples the communication substrate 600 and the control substrate 500, in which the communication substrate 600 is supported by a clay-like support column CY having an electrical insulation property with respect to the control substrate 500.

According to Additional Note 1-1, since the communication substrate 600 and the control substrate 500 are coupled to each other by the substrate-to-substrate connector CN, and the communication substrate 600 is supported by the support column CY with respect to the control substrate 500, a change in the relative position and posture between the communication substrate 600 and the control substrate 500 can be suppressed as compared with an aspect in which the support column CY is not provided. Therefore, according to Additional Note 1-1, a surface damage in the communication substrate 600 and the control substrate 500 which is caused by the change in the relative position and posture of the communication substrate 600 and the control substrate 500 can be suppressed, and the possibility of occurrence of the fretting corrosion caused by the surface damage in the communication substrate 600 and the control substrate 500 can be reduced.

### Additional Note 1-2

According to Additional Note 1-2, the ink jet printer 1 according to Additional Note 1-1 further includes: a transport unit 9 including a belt 97 that transports the head unit 3 and a medium transport mechanism 93 that transports the recording paper PP, in which the drive control circuit 50 controls the transport unit 9 and the head unit 3 such that the head unit 3 forms an image on the recording paper PP while the head unit 3 is transported by the belt 97.

According to Additional Note 1-2, even when a vibration is generated due to the transport of the head unit 3 by the transport unit 9, since the communication substrate 600 is supported by the support column CY, the change in the relative position and posture of the communication substrate 600 and the control substrate 500 can be suppressed.

### Additional Note 1-3

According to Additional Note 1-3, in the ink jet printer 1 according to Additional Note 1-1 or 1-2, the communication substrate 600 includes a lower surface 6001 supported by the support column CY and an upper surface 6002 opposite to the lower surface 6001, and an antenna 61 for performing wireless communication is provided on the upper surface 6002.

According to Additional Note 1-3, the possibility that transmission and reception of a signal in the antenna 61 is inhibited can be reduced.

### Additional Note 1-4

According to Additional Notes 1-4, in the ink jet printer 1 according to Additional Notes 1-1 to 1-3, the support column CY overlaps an electronic component included in the drive control circuit 50 when the communication substrate 600 is viewed in a plan view.

According to Additional Note 1-4, the height of the support column CY is reduced, and the communication substrate 600 can be stably supported by the support column CY as compared with an aspect in which the support column CY is provided not to overlap the electronic component.

### Additional Note 1-5

According to Additional Note 1-5, in the ink jet printer 1 according to Additional Notes 1-1 to 1-4, the support column CY includes a base material SL that is heat conductive and formed of silicone clay, and heat conductive particles PT added to the base material SL.

According to Additional Note 1-5, heat generated from the drive control circuit 50 provided on the control substrate 500 can be efficiently dissipated via the support column CY.

### Additional Note 1-6

According to Additional Note 1-6, in the ink jet printer 1 according to Additional Notes 1-1 to 1-4, the support column CY is formed of silicone clay.

According to Additional Note 1-6, the change in the relative position and posture between the communication substrate 600 and the control substrate 500 can be suppressed.

### Additional Note 1-7

According to Additional Note 1-7, in the ink jet printer 1 according to Additional Note 1-4, the electronic component is an electrolytic capacitor Cd such as an aluminum electrolytic capacitor.

According to Additional Note 1-7, the height of the support column CY is reduced, and the communication substrate 600 can be stably supported by the support column CY as compared with an aspect in which the support column CY is provided not to overlap the electrolytic capacitor Cd. In addition, according to Additional Note 1-7, since the support column CY is provided to overlap the electrolytic capacitor Cd having a simple shape as compared with other electronic components, as compared with an aspect in which the support column CY is provided to overlap the other electronic components, the possibility that a gap is generated between the support column CY and the electrolytic capacitor Cd is reduced, and the communication substrate 600 can be stably supported by the support column CY.

### Additional Note 1-8

According to Additional Note 1-8, in the ink jet printer 1 according to Additional Note 1-4, the electronic component is an inductor L0 covered with a shield.

According to Additional Note 1-8, since the inductor L0 has a surface shape with less irregularities as compared with an aspect in which the inductor L0 does not include the shield, the possibility that a gap is generated between the support column CY and the inductor L0 can be reduced, and a stable support of the communication substrate 600 by the support column CY can be realized. Further, according to Additional Note 1-8, as compared with an aspect in which the inductor L0 does not include the shield, separation between the support column CY and the inductor L0 is facilitated, and reusability of the inductor L0 can be improved.

### Additional Note 1-9

According to Additional Note 1-9, the ink jet printer 1 according to Additional Notes 1-1 to 1-8 is portable.

According to Additional Note 1-9, even when a vibration is generated due to carrying of the ink jet printer 1, since the communication substrate 600 is supported by the support column CY, the change in the relative position and posture of the communication substrate 600 and the control substrate 500 can be suppressed.

### Additional Note 1-10

According to Additional Note 1-10, in the ink jet printer 1 according to Additional Notes 1-1 to 1-9, a color of the support column CY is different from at least one of colors of the communication substrate 600 and the control substrate 500.

According to Additional Note 1-10, since at least one of workloads of the work of separating the support column CY and the control substrate 500 and the work of separating the support column CY and the communication substrate 600 can be reduced, at least one of the control substrate 500 and the communication substrate 600 can be easily reused, and an environmental load of the ink jet printer 1 can be reduced.

### D. 2. Additional Note 2

Hereinafter, a smartphone 1B according to Additional Note 2 will be described.

### Additional Note 2-1

According to Additional Note 2-1, there is provided a smartphone 1B including a control substrate 500B; a communication substrate 600; and a substrate-to-substrate connector CN that couples the control substrate 500B and the communication substrate 600 and transmits an electric signal between the control substrate 500B and the communication substrate 600, in which the communication substrate 600 is supported by a clay-like support column CY having electrical insulation property with respect to the control substrate 500B.

According to Additional Note 2-1, since the communication substrate 600 and the control substrate 500B are coupled to each other by the substrate-to-substrate connector CN, and the communication substrate 600 is supported by the support column CY with respect to the control substrate 500B, the change in the relative position and posture between the communication substrate 600 and the control substrate 500B can be suppressed as compared with an aspect in which the support column CY is not provided. Therefore, according to Additional Note 2-1, a surface damage in the communication substrate 600 and the control substrate 500B which is caused by the change in the relative position and posture of the communication substrate 600 and the control substrate 500B can be suppressed, and the possibility of occurrence of the fretting corrosion caused by the surface damage to the communication substrate 600 and the control substrate 500B can be reduced.

### Additional Note 2-2

According to Additional Note 2-2, in the smartphone 1B according to Additional Notes 2-1, when the communication substrate 600 is viewed in a plan view, the communication substrate 600 includes an end portion region Ar1 including one end portion Eg1 of the communication substrate 600, an end portion region Ar2 including another end portion Eg2 of the communication substrate 600, and an intermediate region Ar0 between the end portion region Ar1 and the end portion region Ar2, the substrate-to-substrate connector CN is coupled to the communication substrate 600 in the end portion region Ar1, and the support column CY supports the communication substrate 600 in the end portion region Ar2.

According to Additional Note 2-2, since the substrate-to-substrate connector CN is coupled to the communication substrate 600 in the end portion region Ar1, and the support column CY supports the communication substrate 600 in the end portion region Ar2, the communication substrate 600 can be more stably supported by the control substrate 500B as compared with an aspect in which one or both of the substrate-to-substrate connector CN and the support column CY are provided in the intermediate region Ar0.

### Additional Note 2-3

According to Additional Note 2-3, in the smartphone 1B according to Additional Note 2-1 or 2-2, the support column CY is provided at a position overlapping an electrolytic capacitor Cd provided on the control substrate 500B when the control substrate 500B is viewed in a plan view.

According to Additional Note 2-3, the height of the support column CY is reduced, and the communication substrate 600 can be stably supported by the support column CY as compared with an aspect in which the support column CY is provided not to overlap the electrolytic capacitor Cd.

### Additional Note 2-4

According to Additional Note 2-4, in the smartphone 1B according to Additional Note 2-3, the electrolytic capacitor Cd is larger than another electronic components provided at a position of the control substrate 500B which does not overlap the support column CY when the control substrate 500B is viewed in a plan view.

According to Additional Note 2-4, the height of the support column CY is reduced as compared with an aspect in which the electrolytic capacitor Cd is smaller than the other electronic component, and the communication substrate 600 can be stably supported by the support column CY.

### Additional Note 2-5

According to Additional Note 2-5, in the smartphone 1B according to Additional Note 2-3, the support column CY is provided at a position overlapping the communication control circuit 62 provided on the communication substrate 600 when the communication substrate 600 is viewed in a plan view.

According to Additional Note 2-5, the height of the support column CY is reduced, and the communication substrate 600 can be stably supported by the support column CY as compared with an aspect in which the support column CY is provided not to overlap the communication control circuit 62.

### Additional Note 2-6

According to Additional Note 2-6, in the smartphone 1B according to Additional Notes 2-1 to 2-5, the support column CY includes a base material SL that is heat conductive and formed of silicone clay, and heat conductive particles PT added to the base material SL.

According to Additional Note 2-6, heat generated from the drive control circuit 50B provided on the control substrate 500B can be efficiently dissipated via the support column CY.

### Additional Note 2-7

According to Additional Note 2-7, in the smartphone 1B according to Additional Notes 2-1 to 2-5, the support column CY is formed of silicone clay.

According to Additional Note 2-7, the change in the relative position and posture between the communication substrate 600 and the control substrate 500B can be suppressed.

### Additional Note 2-8

According to Additional Note 2-8, the smartphone 1B according to Additional Notes 2-1 to 2-7 is portable.

According to Additional Note 2-8, even when a vibration is generated due to carrying of the smartphone 1B, since the communication substrate 600 is supported by the support column CY, the change in the relative position and posture of the communication substrate 600 and the control substrate 500B can be suppressed.

### Additional Note 2-9

According to Additional Note 2-9, in the smartphone 1B according to Additional Notes 2-1 to 2-8, the communication substrate 600 has one side of 1 inch or less, and a communication control circuit 62 that executes wireless communication is provided on the communication substrate 600.

According to Additional Note 2-9, even when a vibration occurs in the smartphone 1B, since the size of the communication substrate 600 supported by the support column CY is small, the change in the relative position and posture of the communication substrate 600 and the control substrate 500B can be suppressed.

What is claimed is:

1. An electronic device, comprising:
a first substrate;
a second substrate; and
a coupling component that couples the first substrate and the second substrate, and transmits an electric signal between the first substrate and the second substrate, wherein
the second substrate is supported by a clay-like support column having an electrical insulation property with respect to the first substrate.

2. The electronic device according to claim 1, wherein
when the second substrate is viewed in a plan view, the second substrate includes a first region including one end portion of the second substrate, a second region including another end portion of the second substrate, and an intermediate region between the first region and the second region,
the coupling component is coupled to the second substrate in the first region, and
the support column supports the second substrate in the second region.

3. The electronic device according to claim 1, wherein
the support column is provided at a position overlapping a first electronic component provided on the first substrate when the first substrate is viewed in a plan view.

4. The electronic device according to claim 3, wherein
the first electronic component is larger than another electronic component provided at a position of the first substrate which does not overlap the support column when the first substrate is viewed in a plan view.

5. The electronic device according to claim 3, wherein
the support column is provided at a position overlapping a second electronic component provided on the second substrate when the second substrate is viewed in a plan view.

6. The electronic device according to claim 1, wherein
the support column includes a base material that is heat conductive and formed of silicone clay, and heat conductive particles added to the base material.

7. The electronic device according to claim 1, wherein
the support column is formed of silicone clay.

8. The electronic device according to claim 1, wherein
the electronic device is portable.

9. The electronic device according to claim 1, wherein
the second substrate has one side of 1 inch or less, and
the second substrate is provided with a communication circuit that executes wireless communication.
